(19) United States
(12) Patent Application Publication
(10) Pub. No.: US 2024/0093063 A1
(43) Pub. Date: Mar. 21, 2024

(54) METHOD FOR TRANSFERRING AN ADHESIVE LAYER OF THERMOPLASTIC POLYMER(S) FROM A FIRST SUBSTRATE TO A SECOND SUBSTRATE

(71) Applicant: COMMISSARIAT À L'ÉNERGIE ATOMIQUE ET AUX ÉNERGIES ALTERNATIVES, Paris (FR)

(72) Inventors: Pierre Montmeat, Grenoble (FR); Frank Fournel, Grenoble (FR); Grégory Enyedi, Grenoble (FR); Simon Vaudaine, Grenoble (FR)

(21) Appl. No.: 18/456,604

(22) Filed: Aug. 28, 2023

(30) Foreign Application Priority Data
Aug. 30, 2022 (FR) 2208678

(51) Int. Cl. C09J 7/20

(52) U.S. Cl. CPC C09J 7/201; C09J 2203/326; C09J 2301/50

(57) ABSTRACT

A method for transferring an adhesive layer of thermoplastic polymer(s) from a first substrate to a second substrate including: depositing an antiadhesive layer on a first substrate, this layer being deposited on the periphery of the top face of said substrate, referred to as peripheral layer, thus providing on said top face a zone devoid of said layer, referred to as central zone; depositing an adhesive layer of thermoplastic polymer(s) on said central zone; depositing an antiadhesive layer on a second substrate, this layer being deposited on the top face of the second substrate excluding its periphery, said periphery being thus devoid of said antiadhesive layer; bonding the first substrate and the second substrate consisting of thermocompressing the top face of the first substrate onto the top face of the second substrate; removing the first substrate, whereby the second substrate remains, of which the top face is coated by the adhesive layer of thermoplastic polymer(s).

### CROSS-REFERENCE TO RELATED APPLICATIONS

This application claims priority from French Patent Application No. 2208678 filed on Aug. 30, 2022. The content of this application is incorporated herein by reference in its entirety.

### TECHNICAL FIELD

The invention relates to a method for transferring an adhesive layer of thermoplastic polymer(s) from a first substrate to a second substrate, this second substrate being capable of being subsequently used in temporary bonding techniques for example, for the design of electronic components.

More specifically, the temporary bonding techniques find an application in the manufacture of electronic components, such as integrated circuits, on two faces of a plate, for example, made of silicon, such a manufacture requiring the set-up on one of the faces of the plate of a temporary substrate (or temporary handle) to be able to handle said plate and integrate electronic compounds on the other face not occupied by the temporary substrate. This temporary substrate intended as its name indicates to be removed from the face occupied thereby therefore undergoes temporary bonding on the face in question.

Conventionally, the manufacture of electronic components on two faces of a plate (hereinafter referred to as substrate of interest) involving temporary bonding comprises the following steps illustrated in FIG. 1 appended:
a step of depositing on the top face 1 of a substrate of interest 3, referred to as S1, (for example, a silicon plate) already equipped with electronic components 5 an adhesive layer 7 (for example, a layer of adhesive thermoplastic polymer(s));
a step of bonding, on said top face of the substrate of interest, a temporary substrate 9, referred to as S2 (or temporary handle), for example, by thermocompression, said substrate making it possible, on one hand, to conceal and protect the top face and serving, on the other, as a grip to be able to handle the substrate of interest without degrading this top face, the temporary substrate including, on its face intended to be in contact with the top face of the substrate of interest, an antiadhesive dismounting layer 11;
a step of producing electronic components 13 on the free bottom face 15 (opposite the top face) of the substrate of interest;
a step of removing the temporary substrate 9 from the top face of the substrate of interest, this removal step being facilitated by the nature of the dismounting layer, which ensures poor adherence between the adhesive layer and the temporary substrate;
a step of eliminating the adhesive layer 7 from the top face, whereby a substrate of interest equipped with electronic components both on its top face and on its bottom face remains.

The adhesive layer is conventionally composed of one or more thermoplastic polymers with adhesive properties provided, for example, via a liquid formulation comprising said thermoplastic polymer(s) and at least one organic solvent. In this case, the adhesive layer is formed by depositing, for example, by spin coating, the liquid formulation on the top face of the substrate of interest then by heat-treating the deposited layer to eliminate the organic solvent(s) therefrom.

It can be difficult or even impossible to deposit an adhesive layer on a substrate of interest, for the following reasons:
the electronic components present on the top face of the substrate of interest or the substrate of interest per se cannot withstand the heat treatment required for the formation of the adhesive layer;
the top face of the substrate of interest has insufficient wettability to ensure homogeneous and covering deposition of the liquid formulation;
the substrate of interest has an incompatibility with the device for depositing the liquid formulation (for example, in terms of thickness, type of material, metal contamination);
the topography of the substrate of interest is not suitable for the method for depositing the liquid formulation and for the steps subsequent to deposition.

To remedy these limitations and drawbacks, it should be possible to introduce the adhesive layer other than by deposition on the substrate of interest, for example, by adding this layer to the temporary substrate.

Therefore, based on this analysis, the inventors have developed a solution for adding an adhesive layer to the temporary substrate, this solution fitting more generally into a method for transferring an adhesive layer of thermoplastic polymer(s) from one substrate to another.

### DESCRIPTION OF THE INVENTION

Thus, the invention relates to a method for transferring an adhesive layer of thermoplastic polymer(s) from a first substrate to a second substrate comprising the following steps:
a step of depositing an antiadhesive layer on a first substrate, this layer being deposited on the periphery of the top face of said substrate, referred to as peripheral layer, thus providing on said top face a zone devoid of said layer, referred to as central zone;
a step of depositing an adhesive layer of thermoplastic polymer(s) on said central zone;
a step of depositing an antiadhesive layer on a second substrate, this layer being deposited on the top face of the second substrate excluding its periphery, said periphery being thus devoid of said antiadhesive layer;
a step of bonding the first substrate and the second substrate consisting of thermocompressing the top face of the first substrate onto the top face of the second substrate;
a step of removing the first substrate, whereby the second substrate remains, of which the top face is coated by the adhesive layer of thermoplastic polymer(s).

The method thus enables an effective transfer of an adhesive layer of thermoplastic polymer(s) from a first substrate to a second substrate and, moreover, the adhesive layer of thermoplastic polymer(s) may subsequently be readily detached, in that it only adheres to the second substrate on the periphery of its top face, the remainder of the top face being occupied by an antiadhesive layer. In addition, the adhesive layer may thus be readily subsequently mounted onto another substrate.

As mentioned above, the method according to the invention comprises, firstly, a step of depositing an antiadhesive layer on a first substrate, this layer being deposited at the periphery of the top face of said substrate, referred to as peripheral layer, thus providing on said top face a zone devoid of said layer, referred to as central zone. In other words, after this deposition step, the top face of the first substrate is coated with an antiadhesive peripheral layer, its central zone thus remaining devoid of said layer.

It is specified that top face denotes the face serving as a deposition base on the first substrate and on the second substrate as opposed to the so-called bottom face opposite said top face, which is not subject to any deposition within the scope of this method.

The first substrate and/or the second substrate may be made of a semiconductor material, for example, silicon, germanium or a silicon-germanium alloy and, more specifically, may be a silicon substrate.

The antiadhesive peripheral layer of the first substrate has, as its name indicates, antiadhesive properties and, advantageously, a surface energy less than 20 mJ/m². The surface energy of a solid can be measured by means of the Owens/Wendt method described in the following reference: D. K. Owens; R. C. Wendt, Estimation of the Surface Free Energy of Polymers, in: Journal of Applied Polymer Science Vol. 13, pp. 1741-1747 (1969).

When the first substrate is a circular silicon plate, the antiadhesive peripheral layer is presented, advantageously, in the form of a ring which can have a width greater than or equal to 1 mm.

More specifically, the antiadhesive peripheral layer can be, in particular:
a layer of one or more halogenated polymers, such as a polymer obtained from polymerising at least one fluorinated monomer, for example a fluorinated acrylate monomer, a fluorinated ethylene monomer;
a layer of one or more silane compounds grafted on the first substrate and, more specifically, a layer obtained from reacting one or more halogenosilane compounds with the first substrate (particularly, when the latter is a silicon substrate), the halogenosilane compounds that can be used being, for example, octadecyltrichlorosilane or perfluorodecyltrichlorosilane.

The step of depositing the antiadhesive peripheral layer can comprise, in particular, the following operations:
an operation of contacting the first substrate, at the periphery of its top face, with a liquid composition comprising one or more antiadhesive compounds and at least one organic solvent, the contacting optionally being carried out, for example, by spin coating;
an operation of drying said composition thus deposited by evaporating said solvent(s).

During drying, if the composition comprises one or more halogenosilane compounds and the first substrate is a silicon substrate, the halogenosilane compound(s) will react with the hydroxyl groups present spontaneously on the surface of the silicon substrate to form grafts providing the antiadhesive property at the periphery of the first substrate.

Thus, for example, when the first substrate is a silicon substrate and the halogenosilane compound used is perfluorodecyltrichlorosilane, the antiadhesive peripheral layer thus corresponds to a layer comprising grafts obtained from reacting perfluorodecyltrichlorosilane with the silicon substrate, said grafts complying with the following formula:

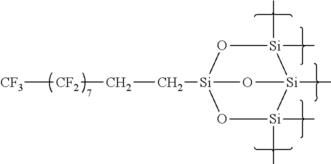

the braces positioned at the silicon atoms belonging to the silicon substrate, the oxygen atoms being obtained from the hydroxyl groups present spontaneously at the surface of a silicon substrate due to a hydration phenomenon linked with ambient humidity. In other words, perfluorodecyltrichlorosilane reacts, according to a nucleophilic substitution mechanism, with the —OH groups present at the surface of the silicon substrate.

Liquid compositions that can be used to form the antiadhesive layer can be commercial compositions supplied by 3M company under the reference NOVEC™ 2702, NOVEC™ 1700 or NOVEC™ 1720 or the commercial compositions marketed by Daikin company under the reference Optool.

Before the deposition step mentioned above, the method according to the invention can comprise a step of masking the central zone of the top face of the first substrate, to prevent the antiadhesive layer from also being deposited on this central zone. It is understood, in this case, that after the deposition step, the method may also comprise a step of removing the mask thus introduced.

The masking step can be carried out:
by photolithography; or
by depositing, in a first phase, an adhesive layer on the entire surface of the top face of the first substrate followed, in a second phase, by eliminating, for example, by routing, the adhesive layer, on the periphery of the top face.

Alternatively, the step of depositing an antiadhesive peripheral layer can comprise the following operations:
an operation of contacting the first substrate, at its top face, with a liquid composition comprising one or more antiadhesive compounds and at least one organic solvent, the contacting optionally being carried out, for example, by spin coating;
an operation of drying said composition thus deposited by evaporating said solvent(s);
an operation of eliminating the layer thus obtained at its central zone so as to only allow a peripheral layer to remain.

The elimination operation can be obtained by a mechanical abrasion (for example, by means of a diamond wheel) of the central zone optionally followed by polishing, for example, chemical-mechanical polishing to erase any surface irregularities induced by the mechanical abrasion.

This variant is particularly suitable for a first substrate in which the central zone of the top face is protruding from the periphery thereof, this protrusion possibly resulting from a prior routing operation of the periphery of the top face.

It is understood that, according to this variant, it is not necessary to set up a masking step as described above.

After the step of depositing an antiadhesive layer on the periphery of the top face of the first substrate and the optional step of removing the mask, the method according to the invention comprises a step of depositing on the central zone of the top face of the first substrate an adhesive layer of thermoplastic polymer(s) and, more specifically, of adhesive thermoplastic polymer(s). For example, the layer can be a layer of polyolefin, such as polyethylene, polypropylene; a layer of polyamide; a layer of (ethylene-vinyl acetate) copolymer.

The step of depositing on the central zone can comprise, in particular, the following operations:
an operation of contacting the top face of the first substrate, with a liquid composition comprising a suspension of adhesive polymeric particles in at least one organic solvent, this contacting being carried out, for example, by centrifugation;
an operation of drying said composition thus deposited by evaporating said solvent(s).

Due to the presence of the antiadhesive layer at the periphery of the top face of the first substrate, the adhesive layer of thermoplastic polymer(s) is formed exclusively on the central zone of the top face, which does not comprise the antiadhesive layer.

Liquid compositions that can be used to form the adhesive layer can be commercial BREWER™ 305 compositions marketed by Brewer Science or Zero Newton™ TWM12000 Series marketed by TOKYO OHKA KOGYO Co.

In parallel, the method according to the invention comprises a step of depositing an antiadhesive layer on a second substrate, this layer being deposited on the top face of the second substrate excluding its periphery, said periphery being thus devoid of said layer.

This antiadhesive layer can be of the same type as the antiadhesive layer deposited on the first substrate.

More specifically, the antiadhesive layer of the second substrate can be, in particular:
a layer of one or more halogenated polymers, such as a polymer obtained from polymerising at least one fluorinated monomer, for example a fluorinated acrylate monomer, a fluorinated ethylene monomer;
a layer of one or more silane compounds and, more specifically, a layer obtained from reacting one or more halogenosilane compounds with the first substrate (particularly, when the latter is a silicon substrate), the halogenosilane compounds that can be used being, for example, octadecyltrichlorosilane or perfluorodecyltrichlorosilane.

The step of depositing the antiadhesive layer can comprise, in particular, the following operations:
an operation of contacting the second substrate, at the top face excluding the periphery thereof, with a liquid composition comprising one or more antiadhesive compounds and at least one organic solvent, the contacting optionally being carried out, for example, by spin coating;
an operation of drying said composition thus deposited by evaporating said solvent(s).

During drying, if the composition comprises one or more halogenosilane compounds and the second substrate is a silicon substrate, the halogenosilane compound(s) will react with the hydroxyl groups present spontaneously on the surface of the silicon substrate to form grafts providing the antiadhesive property at the substrate, such as grafts complying with formula (I) mentioned above.

When the second substrate is a circular plate, it can include, after the deposition step, a central circular zone coated with the antiadhesive layer and a peripheral zone devoid of said layer, this peripheral zone forming a ring, which can have a diameter greater than or equal to 1 mm.

As for the step of depositing an antiadhesive peripheral layer for the first substrate, the method according to the invention can comprise a masking step capable of complying with the same conditions as those defined above, except that the mask is affixed to the periphery of the second substrate.

The first substrate and the second substrate can consist of the same material and have identical dimensions and, in particular, the top face of the first substrate and the top face of the second can have the same shape and the same surface area.

In particular, the first substrate and the second substrate can be circular silicon plates having a diameter of 200 mm.

The method comprises a step of bonding the first substrate and the second substrate consisting of thermocompressing the top face of the first substrate onto the top face of the second substrate. Advantageously, for the thermocompression, the central zone of the first substrate coated with an adhesive layer of thermoplastic polymer(s) is placed facing the central zone of the second substrate coated with an antiadhesive layer. Advantageously, the step of bonding by thermocompression is carried out at an effective temperature and pressure to enable spreading of the adhesive layer of thermoplastic polymer(s), so as to enable the junction between the peripheral layer of the first substrate and the peripheral zone of the second substrate. In particular, the temperature applied is advantageously greater than the glass transition temperature (referred to as Tg) of the thermoplastic polymer(s) forming the adhesive layer and, more specifically, can be greater than (Tg+100° C.). Under pressure and at such a temperature, the thermoplastic polymer(s) can become fluid and be subject to creep (particularly, when the viscosity is less than 10⁴ Pa·s) thus making it possible to fill the gap located between the peripheral layer of the first substrate and the peripheral zone of the second substrate.

After the step of bonding by thermocompression, an assembly remains comprising a stack comprising the first substrate and the second substrate between which the adhesive layer of thermoplastic polymer(s) is inserted, said layer being in direct contact with the second substrate via the periphery of said substrate and in indirect contact with the second substrate via the central zone thereof, which is occupied by an antiadhesive layer. The adhesive layer of thermoplastic polymer(s) thus has a greater adherence at the periphery of the second substrate with respect to the periphery of the first substrate, which is coated with an antiadhesive peripheral layer. In addition, this results in an interface having a weak adherence between the adhesive layer of thermoplastic polymer(s) and the periphery of the top face of the first substrate, which enables easier implementation of the last step of the method, namely, the step of removing the first substrate, whereby the second substrate will remain, the top face of which is coated by the adhesive layer of thermoplastic polymer(s).

This removal step can be carried out by inserting a wedge between the first substrate and the second substrate, whereby the interface having the lowest adherence opens. As mentioned above, this consists of the interface between the adhesive layer of thermoplastic polymer(s) and the periphery of the top face of the first substrate, this insertion thus enabling a detachment of the adhesive layer of thermoplastic polymer(s) from the first substrate, said layer remaining, on the other hand, on the top face of the second substrate.

The second substrate resulting from this method thus has, on its top face, an adhesive layer of thermoplastic polymer(s) which has an adherence at the periphery of the top face than the adherence at the central zone of the top face, in the knowledge that this central zone is coated with an antiadhesive layer. This second substrate could thus be used within the scope of a temporary bonding method, as defined above.

A specific embodiment of the method according to the invention is illustrated in FIG. 2 appended, which comprises:
in part A, providing the first substrate 17, referred to as Sgt and the second substrate 19, referred to as S2;
in part B, depositing an antiadhesive peripheral layer 21 on the first substrate 17 and an antiadhesive layer 23 on the central zone of the second substrate;
in part C, depositing an adhesive layer 25 on the central zone of the first substrate;
in part D, placing the top face of the first substrate and the top face of the second substrate facing each other;
in part E, thermocompressing the first substrate and the second substrate;
in part F, removing the first substrate 17, whereby the second substrate 19 remains, of which the top face is coated by the adhesive layer 27 obtained by spreading the adhesive layer 25.

In addition, the invention also relates to a method for manufacturing a substrate of interest comprising a top face and a bottom face, said faces comprising electronic components, said method comprising the following steps:
a step of implementing the transfer method as defined above;
a step of depositing, on the top face of a substrate of interest already equipped with electronic components, the second substrate via its adhesive layer of thermoplastic polymer(s), wherein said second substrate is obtained from the implementation step mentioned above;
a step of producing electronic components on the free bottom face opposite the top face of the substrate of interest;
a step of removing the second substrate from the top face of the substrate of interest, leaving the adhesive layer of thermoplastic polymer(s) remaining on the top face of the substrate of interest;
a step of eliminating the adhesive layer from the top face, whereby a substrate of interest equipped with electronic components both on its top face and on its bottom face remains.

The removal step can comprise, in particular, the following operations:
an operation of eliminating the periphery of the adhesive layer of thermoplastic polymer(s);
an operation of detaching the adhesive layer of thermoplastic polymer(s) from the second substrate in the central zone.

Other features and advantages of the invention will become more apparent on reading the additional description that follows and that relates to examples according to the invention.

Obviously, these examples are given only as an illustration of the subject matter of the invention and in no way form a limitation of this subject matter.

### BRIEF DESCRIPTION OF THE DRAWINGS

FIG. 1 illustrates the different steps of a conventional temporary bonding method.

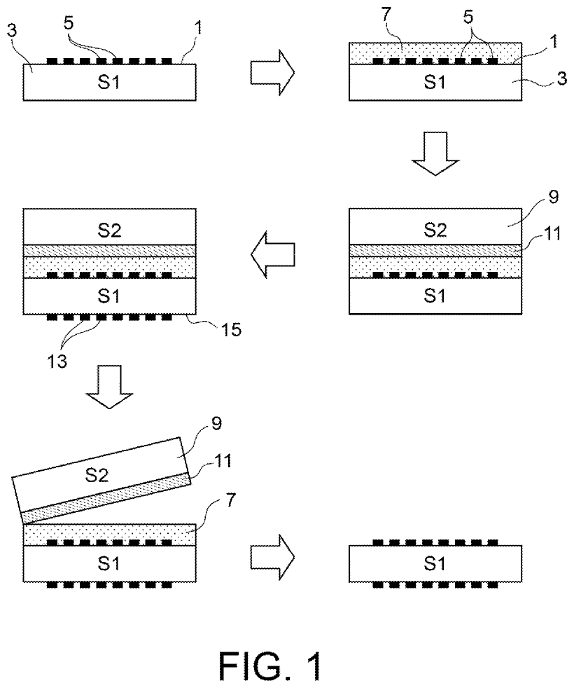

FIG. 2 illustrates the different steps of a specific embodiment of the invention.

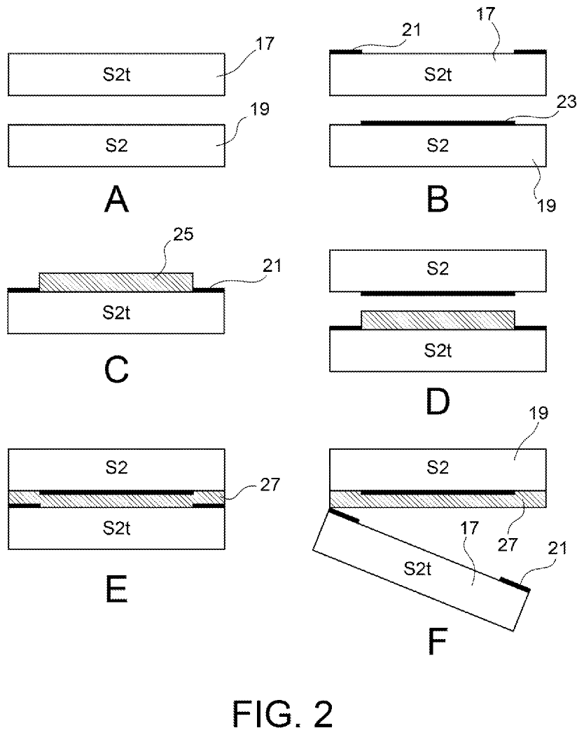

### DETAILED DESCRIPTION OF SPECIFIC EMBODIMENTS

### Example 1

This example illustrates a specific implementation of the transfer method according to the invention.

Masking is carried out by photolithography of the top face of a first silicon plate excluding its periphery followed by the deposition on said periphery of a commercial NOVEC™ 1720 solution comprising a fluorinated compound in solution in a methyl nonafluorobutyl ether solvent and the drying of said commercial solution thus deposited, whereby a peripheral antiadhesive layer remains on the top face of the silicon plate in the form of a strip of a width of 7 mm and having a surface energy of 11 mJ/m². The mask is then removed to release the central zone of the top face of said plate.

In parallel, deposition is carried out on the entire surface of the top face of a second silicon plate of the same commercial NOVEC™ 1720 solution as well as the drying of said solution thus deposited, whereby an antiadhesive layer remains on the entire surface of the top face of the second silicon plate. This adhesive layer is then eliminated only from the periphery of the top face by mechanical routing with a diamond-tipped saw over a depth of 2 μm and a width of 10 mm.

On the central zone of the top face of the first plate an adhesive layer obtained by depositing a commercial product BrewerBond® 305 (comprising polymer chains in D-limonene) followed by drying at 200° C. is deposited by spin coating, said adhesive layer having a thickness of 40 μm.

Then, the top face of the first substrate and the top face of the second substrate are bonded together by thermocompression at a temperature of 250° C. and a force of 15 kN, such conditions enabling the adhesive layer initially present on the top face of the first substrate to creep and spread to ensure contact between the periphery of the first substrate and the periphery of the second substrate. The adherence of the interface between the adhesive layer and the periphery of the second substrate (border not coated with an antiadhesive layer) is 2 J/m², whereas the adherence between the adhesive layer and the periphery of the first substrate is 0.2 J/m². Thanks to this difference in adherence, the second substrate is separated from the first substrate by merely inserting a wedge, taking away the adhesive layer which remains bonded to the second substrate via its periphery.

### Example 2

This example illustrates a specific implementation of the transfer method according to the invention.

Masking is carried out by photolithography of the top face of a first silicon plate excluding its periphery followed by the deposition on said periphery of a commercial NOVEC™ 1720 solution comprising a fluorinated compound in solution in a methyl nonafluorobutyl ether solvent and the drying of said commercial solution thus deposited, whereby an antiadhesive layer remains on the periphery of the top face of the silicon plate in the form of a strip of a width of 2 mm and having a surface energy of 11 mJ/m². The mask is then removed to release the central zone of the top face of said plate.

In parallel, masking is carried out by photolithography of the periphery of the top face (along a width of 2 mm) of a second silicon plate followed by the deposition on the non-masked central zone of the commercial NOVEC™ 1720 solution and the drying of said commercial solution thus deposited.

On the central zone of the top face of the first plate an adhesive layer obtained by depositing a commercial product BrewerBond® 305 (comprising polymer particles in D-limonene) followed by drying at 200° C. is deposited by spin coating, said adhesive layer having a thickness of 40 μm.

Then, the top face of the first substrate and the top face of the second substrate are bonded together by thermocompression at a temperature of 250° C. and a force of 15 kN, such conditions enabling the adhesive layer initially present on the top face of the first substrate to creep and spread to ensure contact between the peripheral layer of the first substrate and the periphery of the second substrate. The adherence of the interface between the adhesive layer and the periphery of the second substrate (border not coated with an antiadhesive layer) is 2 J/m², whereas the adherence between the adhesive layer and the periphery of the first substrate is 0.2 J/m². Thanks to this difference in adherence, the second substrate is separated from the first substrate by merely inserting a wedge, taking away the adhesive layer which remains bonded to the second substrate via its periphery.

### Example 3

This example illustrates a specific implementation of the transfer method according to the invention.

Rolling is carried out on the top face of a first silicon plate of a Lintec Adwill® D610 type adhesive sheet followed by routing of the sheet thus laminated at the periphery of the top face along a width of 1 mm by means of an automatic diamond-tipped saw, whereby a peripheral zone remains from which the adhesive sheet has been removed.

The assembly is then submerged in a commercial NOVEC™ 2702 solution then dried by centrifugation. The adhesive sheet, which remains on the central zone of the top face, is insolated by applying UV radiation, then is detached from its substrate. The top face of the first plate thus includes an antiadhesive peripheral layer, which has a surface energy of 5 mJ/m².

In parallel, masking is carried out by photolithography of the periphery of the top face (along a width of 1 mm) of a second silicon plate followed by the deposition on the non-masked central zone of a commercial NOVEC™ 2702 solution and the drying of said commercial solution thus deposited.

On the central zone of the top face of the first plate, an adhesive layer obtained by depositing a commercial product BrewerBond® 305 (comprising polymer chains in D-limonene) followed by drying at 200° C. is deposited by spin coating, said adhesive layer having a thickness of 40 μm.

Then, the top face of the first substrate and the top face of the second substrate are bonded together by thermocompression at a temperature of 250° C. and a force of 15 kN, such conditions enabling the adhesive layer initially present on the top face of the first substrate to creep and spread to ensure contact between the peripheral layer of the first substrate and the periphery of the second substrate. The adherence of the interface between the adhesive layer and the periphery of the second substrate (border not coated with an antiadhesive layer) is 2 J/m², whereas the adherence between the adhesive layer and the periphery of the first substrate is 0.2 J/m². Thanks to this difference in adherence, the second substrate is separated from the first substrate by merely inserting a wedge, taking away the adhesive layer which remains bonded to the second substrate via its periphery.

### Example 4

This example illustrates a specific implementation of the transfer method according to the invention.

Masking is carried out by photolithography of the top face of a first silicon plate excluding its periphery followed by the deposition on said periphery of a solution comprising perfluorodecyltrichlorosilane and isooctane and the drying of said solution thus deposited, whereby an antiadhesive layer remains at the periphery of the top face of the silicon plate in the form of a strip of a width of 5 mm and having a surface energy of 10 mJ/m². The mask is then removed to release the central zone of the top face of said plate.

In parallel, deposition is carried out on the entire surface of the top face of a second silicon plate of a solution of perfluorodecyltrichlorosilane in isooctane as well as the drying of said solution thus deposited, whereby an antiadhesive layer remains on the entire surface of the top face of the second silicon plate. This adhesive layer is then eliminated only from the periphery of the top face by routing with a diamond-tipped saw over a depth of 10 μm and a width of 3 mm, the adhesive layer remaining on the central zone of the top face of the second plate having a surface energy of 10 mJ/m².

On the central zone of the top face of the first plate, an adhesive layer obtained by depositing a commercial product Zero Newton™ TWM12000 Series obtained from the supplier TOK (Tokyo Ohka Kogyo Product) followed by drying at 220° C. is deposited by spin coating, said adhesive layer having a thickness of 100 μm.

Then, the top face of the first substrate and the top face of the second substrate are bonded together by thermocompression at a temperature of 240° C. and a force of 20 kN, such conditions enabling the adhesive layer initially present on the top face of the first substrate to creep and spread to ensure contact between the peripheral layer of the first substrate and the periphery of the second substrate. The adherence of the interface between the adhesive layer and the periphery of the second substrate (border not coated with an antiadhesive layer) is 3 J/m², whereas the adherence between the adhesive layer and the periphery of the first substrate is 0.9 J/m². Thanks to this difference in adherence, the second substrate is separated from the first substrate by merely inserting a wedge, taking away the adhesive layer which remains bonded to the second substrate via its periphery.

### Example 5

This example illustrates a specific implementation of the transfer method according to the invention.

By means of a diamond-tipped saw, a first silicon plate is routed, on the periphery of its top face, over a width of 2 mm and a depth of 15 μm, whereby a first silicon plate remains of which the central zone of the top face protrudes from its periphery. The first silicon plate thus routed is then submerged in a solution of octadecyltrichlorosilane in isooctane then dried by centrifugation, whereby an antiadhesive layer coats the entire top face both on it protruding central zone and on its periphery. The antiadhesive layer has a surface energy of 17 mJ/m². By means of a diamond wheel, the central zone is subjected to mechanical abrasion so as to eliminate 10 μm of thickness and, moreover, the antiadhesive layer at the surface of the central zone. Said central zone is then subjected to chemical-mechanical polishing so as to erase the irregularities induced by the mechanical abrasion. After this polishing, on the central zone of the top face of the first plate, an adhesive layer obtained by depositing the commercial product BrewerBond® 305 (comprising polymer particles in D-limonene) followed by drying at 200° C. is deposited by spin coating, said adhesive layer having a thickness of 50 μm.

In parallel, masking is carried out by photolithography of the periphery of the top face (along a width of 1 mm) of a second silicon plate followed by the deposition on the non-masked central zone of a solution of octadecyltrichlorosilane in isooctane and the drying of said solution thus deposited. After removing the mask, a silicon plate results, the top face of which is coated on its central zone with an antiadhesive layer and the periphery is devoid of said layer along an outer strip of 2 mm.

Then, the top face of the first substrate and the top face of the second substrate are bonded together by thermocompression at a temperature of 250° C. and a force of 15 kN, such conditions enabling the adhesive layer initially present on the top face of the first substrate to creep and spread to ensure contact between the peripheral layer of the first substrate and the periphery of the second substrate. The adherence of the interface between the adhesive layer and the periphery of the second substrate (border not coated with an antiadhesive layer) is 2 J/m², whereas the adherence between the adhesive layer and the periphery of the first substrate is 0.1 J/m². Thanks to this difference in adherence, the second substrate is separated from the first substrate by merely inserting a wedge, taking away the adhesive layer which remains bonded to the second substrate via its periphery.

1. A method for transferring an adhesive layer of thermoplastic polymer(s) from a first substrate (17) to a second substrate (19) comprising the following steps:
a step of depositing an antiadhesive layer on a first substrate (17), this layer being deposited on a periphery of the top face of this substrate, referred to as an antiadhesive peripheral layer (21), thus providing on the top face a zone devoid of this layer, referred to as central zone;
a step of depositing as adhesive layer (25) of thermoplastic polymer(s) on the central zone;
a step of depositing an antiadhesive layer (23) on a second substrate (19), this layer being deposited on the top face of the second substrate excluding its periphery, the periphery being thus devoid of the antiadhesive layer;
a step of bonding the first substrate (17) and the second substrate (19) consisting of thermocompressing the top face of the first substrate (17) onto the top face of the second substrate (19);
a step of removing the first substrate (17), whereby the second substrate (19) remains, of which the top face is coated by the adhesive layer of thermoplastic polymer(s).

2. The method of claim 1, wherein the first substrate (17) and/or the second substrate (19) is (are) made of a semiconductor material.

3. The method of claim 2, wherein the first substrate (17) and/or the second substrate (19) is (are) made of silicon, germanium or silicon-germanium alloy.

4. The method of claim 3, wherein the first substrate (17) and/or the second substrate (19) is (are) a silicon substrate.

5. The method of claim 1, wherein the antiadhesive peripheral layer (21) has a surface energy less than 20 J/m².

6. The method of claim 1, wherein, when the first substrate (17) is a circular silicon plate, the antiadhesive peripheral layer (21) is in a form of a ring.

7. The method of claim 6, wherein the ring has a width greater than or equal to 1 mm.

8. The method of claim 1, wherein the antiadhesive peripheral layer (21) is:
a layer of one of more halogenated polymers; or
a layer of one or more silane compounds grafted onto the first substrate.

9. The method of claim 1, wherein, when the antiadhesive peripheral layer (21) is made of one or more silane compounds grafted onto the first substrate, this layer is obtained from reacting one or more halogenosilane compounds with the first substrate.

10. The method of claim 9, wherein, when the first substrate (17) is a silicon substrate and the halogenosilane compound used is perfluorodecyltrichlorosilane, the antiadhesive peripheral layer (21) corresponds to a layer comprising grafts obtained from reacting perfluorodecyltrichlorosilane with the silicon substrate, the grafts having formula:

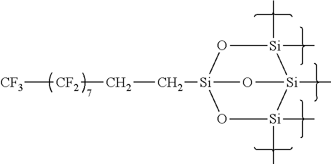

11. The method of claim 1, wherein the step of depositing the antiadhesive peripheral layer (21) comprises:
an operation of contacting the first substrate, at the periphery of its top face, with a liquid composition comprising one or more antiadhesive compounds and at least one organic solvent;
an operation of drying the composition thus deposited by evaporating the solvent(s).

12. The method of claim 1, further comprising, before the step of depositing the antiadhesive peripheral layer, a step of masking the central zone of the top face of the first substrate (17).

13. The method of claim 12, wherein the masking step is carried out:
by photolithography; or
by depositing, in a first phase, an adhesive layer on the entire surface of the top face of the first substrate followed, in a second phase, by eliminating the adhesive layer, on the periphery of the top face.

14. The method of claim 1, wherein the step of depositing on the central zone comprises the following operations:
contacting the top face of the first substrate (17), with a liquid composition comprising a suspension of adhesive polymeric particles in at least one organic solvent;
drying the composition thus deposited by evaporating the solvent(s).

15. The method of claim 1, wherein the first substrate (17) and the second substrate (19) consist of a same material and have identical dimensions.

16. The method of claim 1, wherein the removal step is carried out by inserting a wedge between the first substrate (17) and the second substrate (19).

17. A method for manufacturing a substrate of interest comprising a top face and a bottom face, the faces comprising electronic components, the method comprising the following steps:
implementing the method as defined in claim 1;
depositing, on the top face of a substrate of interest already equipped with electronic components, the second substrate (19) via its adhesive layer of thermoplastic polymer(s), wherein the second substrate is obtained from the implementation step mentioned above;
producing electronic components on the free bottom face opposite the top face of the substrate of interest;
removing the second substrate (19) from the top face of the substrate of interest, leaving the adhesive layer of thermoplastic polymer(s) remaining on the top face of the substrate of interest;
eliminating the adhesive layer from the top face, whereby the substrate of interest equipped with electronic components both on its top face and on its bottom face remains.
